(19) United States
(12) Patent Application Publication
(10) Pub. No.: US 2003/0147223 A1
(43) Pub. Date: Aug. 7, 2003

(54) Memory adapter module for portable computer

(75) Inventor: Wei-Pin Chuang, Taipei (TW)

Correspondence Address: BACON & THOMAS, PLLC, 625 SLATERS LANE, FOURTH FLOOR, ALEXANDRIA, VA, 22314

(73) Assignee: Compal Electronics, Inc., Taipei (TW)

(21) Appl. No.: 10/060,210

(22) Filed: Feb. 1, 2002

(51) Int. Cl. H05K 1/14

(52) U.S. Cl. 361/737

(57) ABSTRACT

Memory adapter module for portable computer, including a casing of the portable computer and a cartridge-like adapter unit. A predetermined portion of the casing is formed with an installation cavity. The adapter unit has a connector at one end. When the adapter unit is inserted into the installation cavity, the connector is electrically connect with a connecting section in the installation cavity. A socket is formed on the other end of the adapter unit. One of various memory units with preset specifications can be selectively inserted into the socket and adapted to the computer. The adapter unit has a modularized structure, whereby a user can replace the adapter unit with another so that various memory units with different specifications can be adapted to the computer without limitation of specification.

### BACKGROUND OF THE INVENTION

The present invention is related to a memory adapter module for portable computer. The adapter unit is modularized, whereby one of various memory units with different specifications can be selectively used and adapted to the computer without limitation of specification.

The current electronic products such as personal computers, electronic dictionaries and digital recorder are often equipped with expansion sockets. An external memory unit can be plugged into the socket to expand the memory capacity of the electronic products and store or process a great amount of complicated digital data. A card-type memory unit has been developed to overcome the problem of volume of hardware. Such card-type memory unit can be easily inserted into or ejected out of the expansion socket.

The card-type memory unit is connected to a portable computer by some measures which can be divided into fixed type connection and adapter-connection. The former is that the main board of the computer is directly formed with an insertion section for inserting the card-type memory unit thereinto. However, the specifications of various card-type memory units are not unified by the manufacturers so that there are various specifications of memory units are commercially available, such as CF, SD, MMC, MMCZ, SM, MS, etc. Therefore, only one single specification of memory unit is unreplaceably applicable to the computer and due to limitation of specification, other specification of memory unit cannot fit in the computer. This results in inconvenience in use of the memory unit. Moreover, with the insertion section directly formed on the main board, it is impossible to minimize the volume of the casing of the computer.

With respect to the latter, an adapter is used to adapt the memory unit to the casing of the computer. A connecting section is directly disposed in the modem card socket of the casing which is originally designed for inserting a modem card therein. The adapter has a connector at one end which can be inserted into the socket to connect with the connecting section. Therefore, a user can replace the adapter with another in accordance with the specification of a desired memory unit so as to adapt the memory unit to the casing. Accordingly, the usable memory unit is not limited to one specific specification.

However, when the adapter is inserted in the socket, the original space for the modem card will be occupied. As a result, a user can only choose the function of communication of the modem or the function of storage of memory unit. It is impossible to at the same time have both functions. This results in inconvenience in use. Moreover, when selectively inserting the memory unit or the modem card into the socket or extracting the memory unit or the modem card out of the socket, a failure of the computer often takes place and the socket tends to have elastic failure. Therefore, the using life is shortened.

### SUMMARY OF THE INVENTION

It is therefore a primary object of the present invention to provide a memory adapter module for portable computer. The modularized adapter unit is replaceable with another adapter unit with different specification so as to enable a user to selectively use one of various memory units with different specifications. In addition, the adapter unit permits a user to have both the function of wireless communication of the modem card and the function of storage of memory unit.

According to the above object, the memory adapter module for portable computer of the present invention includes a cartridge-like adapter unit. A predetermined portion of the casing is formed with an installation cavity. The adapter unit has an insertion socket at one end and a connector at the other end. One of various memory units with preset specifications can be selectively inserted into the socket. A circuit board is disposed in the adapter unit and connected with the connector. When the adapter unit is inserted into the installation cavity of the casing, the connector of the adapter unit is electrically connect with a connecting section in the installation cavity. A user can replace the adapter unit with another so that various memory units with different specifications can be adapted to the computer without limitation of specification.

The present invention can be best understood through the following description and accompanying drawings wherein:

### BRIEF DESCRIPTION OF THE DRAWINGS

FIG. 1 is a perspective view of the adapter unit and the computer casing of the present invention; and

FIG. 2 is a sectional assembled view of the adapter unit and the computer casing of the present invention.

### DETAILED DESCRIPTION OF THE PREFERRED EMBODIMENT

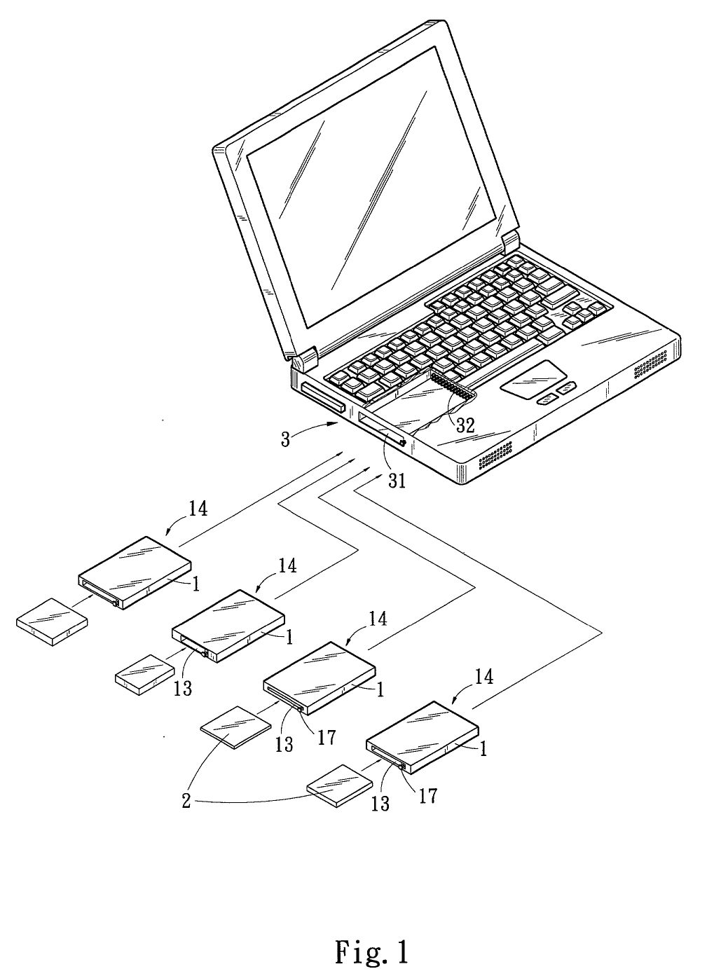

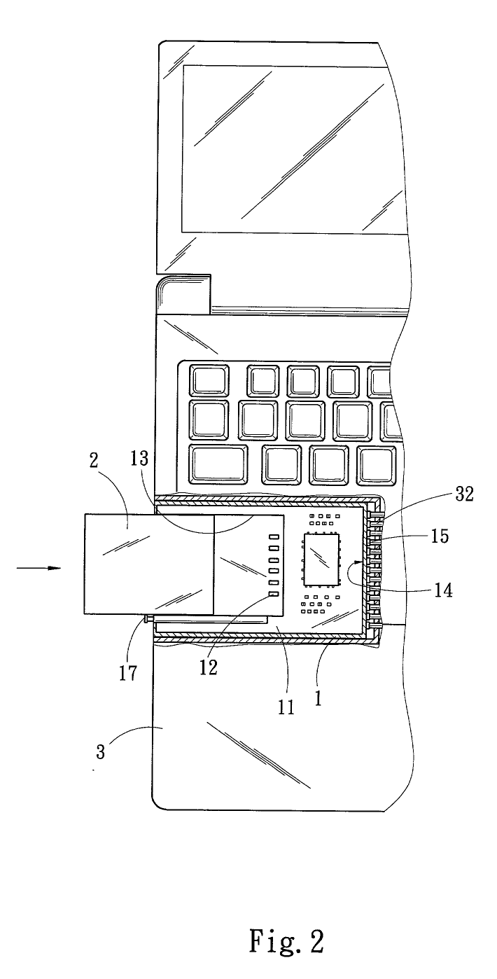

Please refer to FIGS. 1 and 2. The present invention includes an adapter unit 1 and a casing 3 of the portable computer for receiving the adapter unit 1.

The adapter unit 1 is a cartridge body in which a circuit board 11 including a controlling chip is disposed. Signal contact sections 12 are arranged on an edge of the circuit board 11. A socket 13 is formed on one end of the adapter unit 1, whereby one of various memory units 2 with set specifications can be selectively inserted into the socket 13 to electrically contact with the signal contact sections 12. In apreferred embodiment, an ejecting rod 17 is mounted beside the socket 1. A user can press the ejecting rod 17 to eject the memory unit 2 out of the socket 13. An interface is disposed on the other end of the adapter unit 1. Practically, the interface can be a connector 14. The outer end of the connector 14 has an insertion section composed of multiple terminals 15. The inner end of the connector 14 is connected with the circuit board 11.

The casing 3 has a structure substantially identical to that of a conventional casing of a computer. A predetermined portion of the casing 3 is formed with an installation cavity 31 having a connecting section 32. When installed, the insertion section of the adapter unit 1 is first directed to the installation cavity 31 of the casing 3 and inserted thereinto. By means of slightly forcing the adapter unit 1, the terminals 15 of the insertion section can be connected with the connecting section 32 in the installation cavity 31. The adapter unit 1 has a modularized structure, whereby a user can replace the memory with another memory of different specification. Accordingly, the user not only can use the original specification of memory unit 2, but also can use another specification of memory unit by means of replacing the adapter unit 1. Moreover, the adapter unit 1 will not occupy the interior space of the original modem socket so that the user can at the same time use the memory unit for storage and use the modem card for communication and connecting with the internet.

The above embodiment is only used to illustrate the present invention, not intended to limit the scope thereof. Many modifications of the above embodiment can be made without departing from the spirit of the present invention.

What is claimed is:

1. Memory adapter module for portable computer, comprising a casing of the portable computer and an adapter unit, wherein:
a predetermined portion of the casing is formed with an installation cavity having a connecting section therein, whereby the adapter unit can be inserted into the installation cavity to electrically connect with the connecting section; and
the adapter unit is a cartridge body, a connector being disposed at one end of the adapter unit, whereby when the adapter unit is inserted in the installation cavity of the casing, the connector is electrically connect with the connecting section, a socket being formed on the other end of the adapter unit, whereby one of various memory units with preset specifications can be selectively inserted into the socket and adapted to the computer by the adapter unit.

2. Memory adapter module for portable computer as claimed in claim 1, wherein a circuit including controlling chip is disposed in the adapter unit, signal contact sections being arranged on the circuit board and positioned in the socket for electrically connecting with the memory unit.

3. Memory adapter module for portable computer as claimed in claim 1, wherein an ejecting rod is mounted beside the socket, whereby a user can press the ejecting rod to drive an internal push unit to eject the memory unit out of the socket.
